(19) United States
(12) Patent Application Publication
(10) Pub. No.: US 2025/0004037 A1
(43) Pub. Date: Jan. 2, 2025

(54) METHOD FOR PROVIDING A CALIBRATION NUMBER, COMPUTER PROGRAM PRODUCT AND LASER DEVICE FOR CARRYING OUT THE METHOD

(71) Applicant: TRUMPF Photonic Components GmbH, Ulm (DE)

(72) Inventor: Sven Bader, Neu-Ulm (DE)

(21) Appl. No.: 18/882,802

(22) Filed: Sep. 12, 2024

Related U.S. Application Data
(63) Continuation of application No. PCT/EP2023/055373, filed on Mar. 2, 2023.

(30) Foreign Application Priority Data
Mar. 16, 2022 (DE) 10 2022 106 146.9

(51) Int. Cl. G01R 31/26; G01R 35/00; G01S 7/481; G01S 17/04; H01S 5/00; H01S 5/183

(52) U.S. Cl. CPC G01R 31/2635; G01R 35/005; G01S 7/4815; G01S 7/4816; G01S 17/04; H01S 5/0014; H01S 5/183

(57) ABSTRACT

A method for providing a calibration number for optimizing an evaluation of a detection signal obtained from a self-mixing interference of a VCSEL includes measuring a threshold current at which the VCSEL starts to emit a laser light, measuring a working current at a specified power value of the laser light, measuring a working voltage at a specified first electric current value, and determining the calibration number by using a processor based on the threshold current, the working current, and the working voltage.

### CROSS REFERENCE TO RELATED APPLICATIONS

This application is a continuation of International Application No. PCT/EP2023/055373 (WO 2023/174715 A1), filed on Mar. 2, 2023, and claims benefit to German Patent Application No. DE 10 2022 106 146.9, filed on Mar. 16, 2022. The aforementioned applications are hereby incorporated by reference herein.

### FIELD

Embodiments of the present invention relate to a method for providing a calibration number for optimizing an evaluation of a detection signal of a VCSEL obtained by self-mixing interference, in particular for object detection, a computer program product with a computer program and a laser device for carrying out a method.

### BACKGROUND

Produced VCSELs (vertical-cavity surface-emitting lasers) differ from each other with respect to their basic parameters, which affect the efficiency of the VCSELs. These determine, for example, the luminous intensity of the VCSELs. A detection apparatus comprising VCSELs and used, for example, to detect an object is directly influenced by the efficiency of the individual VCSELs, since measurements with VCSELs of different efficiencies can lead to measurement results of different quality. This is due to fluctuations in the signal-to-noise ratio (SNR) of a detection signal from the VCSELs. To avoid this, the VCSELs should be calibrated. For this purpose, methods are known in which predefined detection objects are used to calibrate the detection signals or VCSELs. However, handling the defined detection objects is often difficult and cumbersome.

### SUMMARY

Embodiments of the present invention provide a method for providing a calibration number for optimizing an evaluation of a detection signal obtained from a self-mixing interference of a VCSEL. The method includes measuring a threshold current at which the VCSEL starts to emit a laser light, measuring a working current at a specified power value of the laser light, measuring a working voltage at a specified first electric current value, and determining the calibration number by using a processor based on the threshold current, the working current, and the working voltage.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a flow chart of the method for detecting an object using a VCSEL according to some embodiments;

FIG. 2 shows a wafer with a plurality of VCSELs which are divided by a two-dimensional grid according to some embodiments; and

FIG. 3 shows a laser device with a VCSEL for detecting an object according to some embodiments.

### DETAILED DESCRIPTION

Embodiments of the present invention provide a method which makes it possible to achieve a calibration of the VCSELs without using a defined detection object.

Embodiments of the present invention provide a method for providing a calibration number for optimizing an evaluation of a detection signal of an object detection supported by a VCSEL, comprising the following steps:
measuring a threshold current at which the VCSEL starts to emit laser light,
measuring a working current at a specified power value of the laser light,
in particular measuring a working voltage at a specified first electric current value,
calculating the calibration number by means of a processor unit from the threshold current, the working current and the working voltage.

The detection signal can be obtained from a self-mixing interference of a laser light which is reflected off the object and which enters the VCSEL and/or a photodiode. The object can be, for example, a particle or a plurality of particles, a surface or another object. The parameters measured by the method represent some of the measurable parameters.

The method can be used to create the calibration number, by means of which a calibration of the VCSEL can be achieved without using a defined object. According to this, each VCSEL can be calibrated to an almost equal signal-to-noise ratio of its detection signal, in particular for the detection of a particle distribution, without complex use of particle samples such as defined aerosols or transparent disks provided with particles.

Advantageously, the evaluation of the detection signal is adapted on the basis of the calibration number so that an optimized signal-to-noise ratio of the detection signal of the VCSEL is achieved. This allows a calibration to be simulated using a defined object.

According to the method, a comparison value can be determined by comparing the calculated calibration number with a reference value that represents a correct calibration. The reference value can be stored in a memory. The comparison value can represent a difference between the calibration number and the reference value. This presents an opportunity to optimize the evaluation using a look-up table.

Preferably, the calibration number can be compared with a reference value in a virtual software-supported calibration of the VCSEL, wherein the detection signal is interpreted according to the comparison value in such a way as though a conventional calibration had been carried out. The signal-to-noise ratio of the detection signal can be improved by using a software-supported method to optimize the evaluation.

In an advantageous further development, a wavelength shift of the laser light is measured while the electric current is increased. The wavelength shift is measured, for example, with a linear ramp-up of the current strength.

Furthermore, a wavelength of the laser light emitted by the VCSEL can be measured at a specified second current value. The second current value can be, for example, approximately 1.5 mA and the wavelengths of the laser light from different VCSELs differ, for example due to manufacturing tolerances of their laser cavities.

Preferably, the calibration number is calculated according to a sensitivity characteristic of a photodiode which is provided for receiving a laser light reflected during object detection. A sensitivity curve of the photodiode is used to optimize the evaluation not only on the basis of the measured parameters of the VCSEL.

The laser light emitted from the VCSEL diverges such that the laser light forms a light cone in the far field that forms a far-field angle. The far-field angle can be determined and the calibration number can be set according to this far-field angle.

The calibration number can only be determined once the VCSEL has been manufactured, wherein the calibration number thus determined is stored in a memory. The calibration number can only be determined once during the entire lifetime of the VCSEL.

In an advantageous further development, the calibration number is ascertained before the VCSEL is installed in a device that is provided for object detection. The parameters of newly manufactured VCSELs can be measured at the factory and the calibration number of the VCSEL can be determined.

The method may further include determining the calibration numbers of a plurality of VCSELs arranged on a wafer, wherein the determined calibration numbers are assigned to a two-dimensional grid on the wafer. The grid can be used to create a map-like overview that makes it possible to assign a calibration number to very small individual VCSELs which are difficult to handle.

The calibration number can be ascertained at least once after the VCSEL is installed in a device that is provided for object detection. For example, the calibration number can be determined after the device in which the VCSEL is installed is turned on.

Preferably, the calibration number is determined regularly. The calibration number can be determined at regular intervals after the VCSEL has been installed in a device, or the calibration number can be determined continuously.

The method may be included in a computer program product comprising a computer program containing commands for carrying out the method. Thus, the computer program can be executed, for example, by a processor unit.

A laser device for carrying out the method comprises the VCSEL, the processor unit and the memory. The laser device can be part of a particle detector.

Embodiments of the present invention are explained in more detail below with reference to the associated drawings. Direction indications in the following explanation are to be understood according to the reading direction of the drawings.

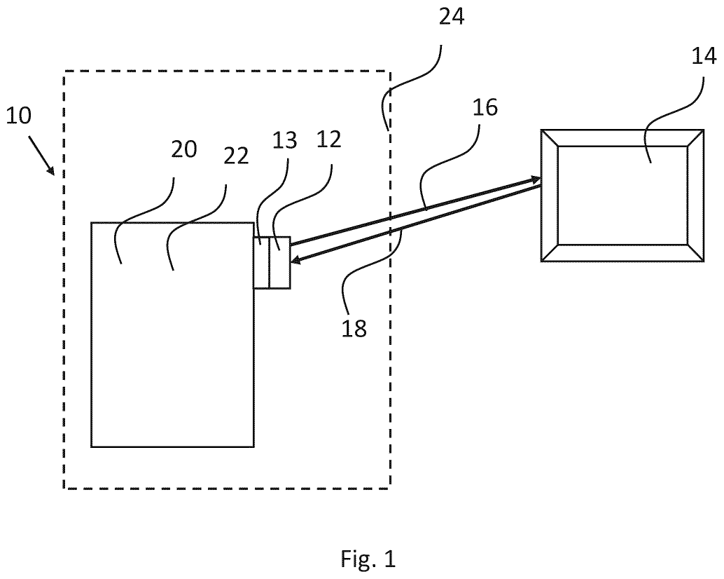

FIG. 1 shows a laser device 10 with a VCSEL 12, which detects an object 14 by means of self-mixing interference. For this purpose, laser light 16 of the VCSEL 12 is reflected off the object 14 and the reflected laser light 18 enters the VCSEL 12 and/or a photodiode. The object 14 can be, for example, a particle or a plurality of particles, a surface or another object such as a body part of a user.

The laser device 10 comprises the VCSEL 12, a processor unit 20 and a memory 22. The laser device 10 can be installed in a device 24 such as a smartphone, a particle detector or a computer mouse or another device for detecting an object 14.

In an alternative exemplary embodiment, the memory 22 and/or the processor unit 20 can be connected to the device 24 via a radio connection. For example, the function of the memory 22 and/or the processor unit 20 can be externalized in the form of a so-called cloud. A so-called host computer or a host network can assume the task of evaluating the detection signal, calculating the calibration number and/or the calibration 34.

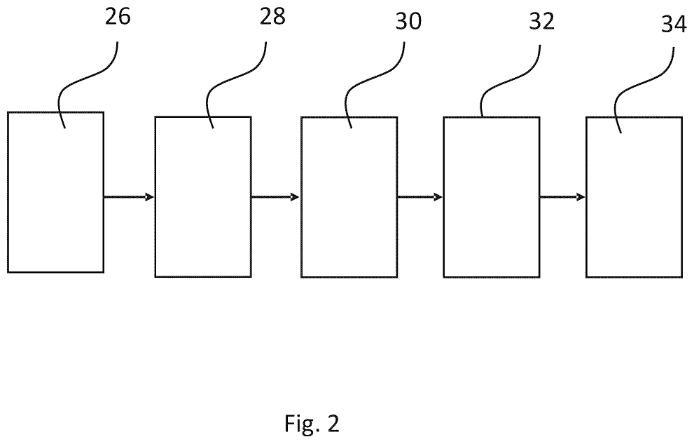

FIG. 2 shows a flow chart of a method for detecting the object 14 using the VCSEL 12. The method provides a calibration number for optimizing an evaluation of a detection signal of an object detection procedure supported by the VCSEL 12. The method comprises the following steps:
measuring 26 a threshold current at which the VCSEL 12 starts to emit a laser light 16,
measuring 28 a working current at a specified power value of the laser light 16,
measuring 30 a working voltage at a specified first electric current value,
calculating 32 the calibration number by means of the processor unit 20 from the threshold current, the working current and the working voltage.

The measurement 26, 28, 30 of the threshold current, the working current and the working voltage can be carried out by a measuring device which is connected to the processor unit 20. The current and voltage may vary from one manufactured VCSEL to another manufactured VCSEL.

The detection signal is obtained from the evaluation of the self-mixing interference of the laser light 18 reflected off the object 14. The evaluation is preferably carried out by the processor device 22.

A calibration 34 of the VCSEL 12 can be carried out by means of the calibration number, without using a reference sample such as a previously known and defined object 14. The calibration 34 serves to obtain the detection signal with a good signal-to-noise ratio from the self-mixing interference. The signal-to-noise ratio of the detection signals of different VCSELs 12 can be set to be approximately the same by calibration 34 using the calibration number.

The calibration number K is related to a threshold current S, a working current A and the working voltage U as follows:

K˜S*A⁻¹

The working current A is preferably to be understood as the current at a certain emission power, where 0.5 mW can be taken as a value purely by way of example.

Furthermore, the calibration number K is proportional to sine (W), where W depends on the working voltage U, the working current A and the threshold current S.

### Preferably,

$$K ∼ S * {A}^{- 1} * {sin}^{2} ( W )$$

such that K is proportional to the square of sine (W).

The variable W therefore depends on the following measurable laser parameters: working voltage U, working current A and threshold current S.

The evaluation of the detection signal is adapted on the basis of the calibration number, which achieves an optimized signal-to-noise ratio of the detection signal of the VCSEL. The detection signal obtained from the self-mixing interference is evaluated in a software-supported manner. Likewise, the method for obtaining the calibration number, calibrating 34 the VCSEL based on the calibration number and adapting the evaluation of the detection signal based on the calibration number is carried out by means of software.

For example, a comparison value can be determined according to the method by comparing the calculated calibration number with a reference value. The reference value represents a calibrated VCSEL 12 having a signal-to-noise ratio which is optimized from the detection signal. The reference value can be stored in a memory 22 from which it can be read out by the processor device 20 in order to be compared with the calibration number by the processor device. For example, the comparison value can represent a difference between the calibration number and the reference value.

The comparison value can be used to read out correction values for the evaluation of the detection signal from a look-up table, by means of which, for example, the software-supported calibration 34 of the VCSELS 12 and finally the optimization of the evaluation can be carried out.

Preferably, for calculating the calibration number, a wavelength shift dL of the laser light 16 is additionally measured which is caused by the increase in the electric current for feeding the VCSEL 12. The wavelength shift dL is measured, for example, with a linear ramp-up of the current strength. Preferably, the ramp-up is carried out between two current points. For example, the first current point can be 1.5 mA and the second current point can be 2.5 mA, so that the current is continuously increased by an amount of 1 mA and the wavelength shift is measured. The wavelength shift dL can be measured directly at the manufacturing site of the VCSEL 12 or by a device 24 in which the VCSEL is installed after its manufacture. For example, the VCSEL 12 could be installed in a smartphone to realize an object detection function, with the smartphone using a sensor or a camera to evaluate reflected light from the laser with respect to its wavelength and thus also the wavelength shift dL. The following relationship exists between the calibration number K and the wavelength shift dL:

K˜dL

Furthermore, the calibration number K also depends on a wavelength L of the laser light 16 emitted by the VCSEL 12, which is measurable at a second current value. Here, sin (W) depends on the wavelength L, where

W˜L.

The second current value can, for example, be approximately 1.5 mA.

If a photodiode 13 is assigned to the VCSEL 12, the sensitivity characteristic PD of the photodiode 13 can be taken into account when calculating the calibration number K, where the calibration number K is inversely proportional to the sensitivity characteristic PD:

$$K ∼ {PD}^{- 1}$$

The laser light 16 emitted from the VCSEL 12 diverges such that the laser light 16 forms a light cone in the far field that forms a far-field angle FA.

If the calibration number K and significant variables that can be determined by the measurable parameters are now considered, the dependence on the self-mixing interference signal SMI, the noise NOISE and the far-field angle FA is striking. The ratio of SMI/NOISE is to be understood as the signal-to-noise ratio SNR. The calibration variable K is dependent as follows:

$$K ∼ SMI / NOISE * {FA}^{2}$$

The self-mixing interference signal SMI depends on the threshold current S and the wavelength shift dL, the noise NOISE depends on the working current A at a certain emission power and the sensitivity characteristic PD, and the far-field angle FA depends on the sin (W).

Preferably, the calibration number is determined only once the VCSEL 12 is manufactured at the VCSEL factory. The calibration number can be determined at a measuring station, where the parameters of the VCSEL 12 such as current, voltage and wavelength are measured. The calibration number thus determined is stored in the memory 22. The calibration number can only be determined once and can be read out from the memory 22 every time an object detection or the evaluation related thereto is to be carried out.

The parameters of the VCSEL 12 can be measured before or after the VCSEL 12 is installed in a device 24.

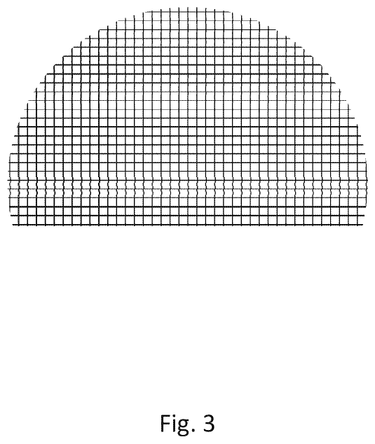

If the VCSEL 12 is measured before installation in a device 24, the VCSEL 12 can be measured at a measuring station while the VCSEL 12 is still arranged on a wafer 36 from the manufacturing process of the VCSEL 12 according to FIG. 3. A plurality of VCSELs 12 can be arranged on the wafer 36. At the measuring station, for example, the threshold current, the working current, the working voltage at a certain first current value, the wavelength shift and/or the wavelength at a certain second current value are ascertained. Alternatively or additionally, the measured parameter values can be converted into the following variables: self-mixing interference signal SMI, noise NOISE and/or the far-field angle FA.

The surface of the wafer 36 on which the VCSELs 12 are arranged is divided into a two-dimensional grid 38 according to the method. The measured parameters can be assigned to a location on the surface of the wafer 36 according to the grid 38. This provides a map-like overview of the efficiency in evaluating a detection signal, such that VCSELs 12 which are assigned to a specific location on the surface can be assigned to the parameters measured there. The same applies to the variables of self-mixing interference signal SMI, noise NOISE and/or far-field angle FA or calibration number.

For example, an optimal calibration number can be determined using a predefined object sample such as a particle sample or a wafer that has already been measured, so that for subsequent undetermined wafers the calculated calibration number can be compared with the optimal calibration number. The optimal calibration number then represents the reference value.

In an alternative embodiment, the VCSEL 12 is installed in a device 24 and the device 24 with the VCSEL 12 is measured accordingly at such a measuring station.

In another alternative embodiment, the VCSEL 12 which is installed in the device 24 can regularly ascertain the parameters, and thus the calibration number, independently. The determination can be carried out continuously while the device 24 is in use, or at regular intervals. The calibration number can be adapted with regard to the temperature and/or the wear of the VCSEL 12. This enables calibration 34 which is stable over time.

Alternatively, the calibration number can be determined only once it has been installed in the device 24 and, for example, switched on by the user of the device 24.

The method may be included in a computer program product comprising a computer program containing commands for carrying out the method. It can be carried out by an ASIC that is either part of the measuring station or the device 24.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A. B and C.

1. A method for providing a calibration number for optimizing an evaluation of a detection signal obtained from a self-mixing interference of a VCSEL, the method comprising:
measuring a threshold current at which the VCSEL starts to emit a laser light,
measuring a working current at a specified power value of the laser light,
measuring a working voltage at a specified first electric current value, and
determining the calibration number by using a processor based on the threshold current, the working current, and the working voltage.

2. The method according to claim 1, further comprising adapting the evaluation of the detection signal based on the calibration number so that an optimized signal-to-noise ratio of the detection signal of the VCSEL is achieved.

3. The method according to claim 1, further comprising determining a comparison value by comparing the calculated calibration number with a reference value that represents a correct calibration.

4. The method according to claim 3, wherein the calibration number is compared with the reference value in a virtual software-supported calibration of the VCSEL, wherein the detection signal is interpreted according to the comparison value in such a way as though a conventional calibration had taken place.

5. The method according to claim 1, further comprising measuring a wavelength shift of the laser light while an electric current is increased.

6. The method according to claim 1, further comprising measuring a wavelength at a specified second current value.

7. The method according to claim 1, wherein the determining the calibration number is performed according to a sensitivity characteristic of a photodiode which is provided for receiving the laser light reflected during object detection.

8. The method according to claim 1, wherein the determining the calibration number is performed according to a far-field angle of the laser light.

9. The method according to claim 1, wherein the calibration number is determined only once after manufacture of the VCSEL, wherein the determined calibration number is stored in a memory.

10. The method according to claim 9, wherein the calibration number is determined before the VCSEL is installed in a device which is provided for object detection.

11. The method according to claim 9, wherein the respective calibration number of the VCSEL of a plurality of VCSELs is determined, wherein the plurality of VCSELs is arranged on a wafer, wherein the determined calibration numbers are assigned to a two-dimensional grid on the wafer.

12. The method according to claim 1, wherein the calibration number is determined at least once after the VCSEL is installed in a device which is provided for object detection.

13. The method according to claim 11, wherein the calibration number is determined regularly over time.

14. A non-transitory computer-readable medium having a computer program stored thereon, the computer program comprising commands for carrying out the method according to claim 1.

15. A laser device for carrying out a method according to claim 1, the laser device comprising the VCSEL, the processor, and a memory.
